(19) United States
(12) Patent Application Publication
(10) Pub. No.: US 2013/0118787 A1
(43) Pub. Date: May 16, 2013

(54) EPOXY RESIN COMPOSITION FOR FORMING PRINTED CIRCUIT BOARD, PRINTED CIRCUIT BOARD MANUFACTURED THEREFROM, AND METHOD FOR MANUFACTURING THE PRINTED CIRCUIT BOARD

(71) Applicants: Tae Hoon Kim, Gyunggi-do (KR); Young Kwan Seo, Gyunggi-do (KR); Jun Young Kim, Seoul (KR); Sung Nam Cho, Gyunggi-do (KR)

(72) Inventors: Tae Hoon Kim, Gyunggi-do (KR); Young Kwan Seo, Gyunggi-do (KR); Jun Young Kim, Seoul (KR); Sung Nam Cho, Gyunggi-do (KR)

(73) Assignee: SAMSUNG ELECTRO-MECHANICS CO., LTD., Gyunggi-do (KR)

(21) Appl. No.: 13/362,406

(22) Filed: Jan. 31, 2012

(30) Foreign Application Priority Data
Nov. 15, 2011 (KR) 1020110118898

(51) Int. Cl. H05K 1/03; C08J 9/28; C08L 63/04

(52) U.S. Cl. 174/258; 523/466; 523/443; 521/64

(57) ABSTRACT

Disclosed herein is an epoxy resin composition including a core-shell structure of microemulsion silica surrounded by surfactant. By using the epoxy resin, surface roughness of a printed circuit board can be formed in an ecofriendly and economic manner. Further, high-reliability microcircuits can be realized by enhancing interface adhesive strength between a resin substrate and a metal layer in a buildup type printed circuit board.

### CROSS REFERENCE TO RELATED APPLICATION

This application claims the benefit of Korean Patent Application No. 10-2011-0118898, filed on Nov. 15, 2011, entitled “Epoxy Resin Composition for Formaing Printed Circuit Board, Printed Circuit Board Produced by the Same, and Production Method Thereof”, which is hereby incorporated by reference in its entirety into this application.

### BACKGROUND OF THE INVENTION

1. Technical Field

The present invention relates to an epoxy resin composition for forming a printed circuit board, a printed circuit board manufactured therefrom, and a method for manufacturing the printed circuit board.

2. Description of the Related Art

With the trend for small size and multiple functions of electronic devices, patterns need to be formed to have high resolution. For this reason, high-resolution of patterns are required to be formed. As for solution of a substrate, wirings of 10 to 12 μm are required in build-up materials, and in the future, wirings of 8 μm or less will be required for resolution beyond the limit. A semi additive process (SAP) is the only one method for mass-producing these wirings. As for manufacturing a substrate for fine wirings, previously, a chemical copper layer having a thickness of almost 2 μm was used, but presently, the thickness thereof is about 1 μm. As the chemical copper layer gets thinner, an adhesion to the substrate needs to be excellent (1 kN). However, when roughness of a resin substrate is formed by a desmear method of the prior art, the roughness of the resin substrate is significantly large, which causes a surface of the chemical copper layer to be also roughened, resulting in deteriorating the adhesion between chemical copper layer and the resin substrate.

In the desmear method of the prior art, if a curing degree of a resin insulation material is high, desired roughness is very difficult to obtain at the time of desmear treatment, and if the curing degree thereof is low, it is difficult to uniformly perform the roughness treatment and many partially engraved portions are generated, and thus, a uniform insulating film can not be obtained. For this reason, methods for forming roughness on an insulating resin having a high curing degree while raising the curing degree of the resin have been studied.

### SUMMARY OF THE INVENTION

As a result of repeated extensive ranges of studies for solving the problems, the present inventors could manufacture a buildup type printed circuit board capable of realizing eco-friendly and high-reliability micro-circuits, by forming a substrate containing a core-shell structure of microemulsion silica surrounded by surfactant, post-curing the resultant substrate, and then forming roughness on the substrate, and thereby complete the present invention based on this result.

The present invention has been made in an effort to provide an epoxy resin composition for forming a printed circuit board capable of realizing high-reliability microcircuits by enhancing interface adhesive strength between a resin substrate and a metal layer in a buildup type printed circuit board.

Further, the present invention has been made in an effort to provide a method for manufacturing a printed circuit board capable of forming roughness of the printed circuit board in an ecofriendly and economic manner, by introducing processes of forming a substrate containing a core-shell structure of microemulsion silica surrounded by surfactant and removing the surfactant to detach silica particles therefrom.

Further, the present invention has been made in an effort to provide a printed circuit board capable of forming uniform roughness and improving physical properties such as a coefficient of thermal expansion (CTE) or the like, by mixing and using microemulsion silica and silica particles.

According to a preferred embodiment of the present invention, there is provided an epoxy resin composition for forming a printed circuit board, including a core-shell structure of microemulsion silica surrounded by surfactant.

The epoxy resin composition may be composed of 14 to 40 wt % of an epoxy resin, 15 to 40 wt % of a curing agent, 20 to 70 wt % of an inorganic filler, and 1 to 5 wt % of microemulsion silica.

The microemulsion silica may have a particle size of 5 to 200 nm.

The epoxy resin may be an aromatic epoxy resin, an alicyclic epoxy resin, a Novolac epoxy resin, an aliphatic epoxy resin, a glycidyl ester epoxy resin, a glycidyl amine type epoxy resin, a glycidyl acryl type epoxy resin, a bisphenol A epoxy resin, a bisphenol F epoxy resin, or a polyester type epoxy resin.

The curing agent may be at least one selected from the group consisting of dicyandiamides, amine-based compounds, derivatives of amine-based compounds, hydrazide compounds, melamine compounds, acid anhydrides, phenol compounds (phenol curing agent), activated ester compounds, benzoxazine compounds, maleimide compounds, heat-curable cationic polymerization catalysts, light-curable cationic polymerization initiators, and cyanate ester resin.

The inorganic filler may be molten silica.

According to another preferred embodiment of the present invention, there is provided a method for manufacturing a printed circuit board, including: providing an epoxy resin composition including a core-shell structure of microemulsion silica surrounded by surfactant; sheeting the epoxy resin composition to form a substrate; and performing surface treatment on the formed substrate by completely post-curing the formed substrate and then removing the surfactant to detach silica particles therefrom.

The epoxy resin composition may be composed of 14 to 40 wt % of an epoxy resin, 15 to 40 wt % of a curing agent, 20 to 70 wt % of an inorganic filler, and 1 to 5 wt % of a microemulsion silica.

The microemulsion silica may have a particle size of 5 to 200 nm.

The epoxy resin may be an aromatic epoxy resin, an alicyclic epoxy resin, a Novolac epoxy resin, an aliphatic epoxy resin, a glycidyl ester epoxy resin, a glycidyl amine type epoxy resin, a glycidyl acryl type epoxy resin, a bisphenol A epoxy resin, a bisphenol F epoxy resin, or a polyester type epoxy resin.

The curing agent may be at least one selected from the group consisting of dicyandiamides, amine-based compounds, derivatives of amine-based compounds, hydrazide compounds, melamine compounds, acid anhydrides, phenol compounds (phenol curing agent), activated ester compounds, benzoxazine compounds, maleimide compounds, heat-curable cationic polymerization catalysts, light-curable cationic polymerization initiators, and cyanate ester resin.

The inorganic filler may be molten silica.

According to still another preferred embodiment of the present invention, there is provided a printed circuit board manufactured in a sheet type by using the epoxy resin composition, wherein the printed circuit board may have a center line average arithmetic roughness of 0.5 μm or less, after the surface treatment is performed thereon.

### BRIEF DESCRIPTION OF THE DRAWINGS

FIG. 1 shows transmission electron microscope (TEM) pictures of microemulsion silica nanoparticles used in the present invention; and

FIG. 2 is a schematic view showing a procedure of forming surface roughness on a substrate containing microemulsion silica according to the present invention.

### DESCRIPTION OF THE PREFERRED EMBODIMENTS

Hereinafter, exemplary embodiments will be described in detail with reference to the accompanying drawings so that they can be easily practiced by those skilled in the art to which the present invention pertains. The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

As described above, in a process of forming a circuit of a buildup type printed circuit board of the prior art, wet roughness is formed by using permanganic acid, and here an insulating layer needs to be used in a semi-dried state. In a case where roughness is formed on a semi-dried substrate by desmear treatment, the level of roughness is locally different or the level of roughness is not easy to control.

According to the present invention, the roughness may be formed by using a substrate containing a core-shell structure of microemulsion silica surrounded by surfactant, and dissolving out the microemulsion silica at the time of the desmear treatment after an insulating material is completely cured. According to the method as above, it is possible to use a completely cured substrate having a high degree of roughness, and thus, uniform coating films can be obtained at the time of the desmear treatment.

An epoxy resin composition for forming a printed circuit board of the present invention contains 1 to 5 wt % of microemulsion silica. Here, the content of silica particles is 20 to 65 wt % in the microemulsion silica. Preferably, the epoxy resin composition for forming a printed circuit board of the present invention is constituted of 15 to 40 wt % of an epoxy resin, 15 to 40 wt % of a curing agent, 20 to 70 wt % of an inorganic filler, and 1 to 5 wt % of microemulsion silica. Here, the optimum curing conditions are made at an equivalent ratio of the epoxy resin to the curing agent in the range of 0.8 to 1.2, thereby designing a crude liquid capable of maintaining a curing degree of 90% or higher.

According to the present invention, if the used amount of microemulsion silica is below 1 wt %, adhesive strength between a substrate and a metal layer can not be enhanced. If the used amount thereof is above 5 wt %, a surface roughness of the desmear-treated substrate cannot be decreased, thereby failing to obtain a substrate having an arithmetical average roughness of 0.5 μm or less in a desmear-treated surface.

The microemulsion silica may be prepared into various sizes of silica particles depending on the kinds and wt % ratios of the surfactant or oil used in preparation thereof, and only one kind thereof may be used or two or more kinds thereof may be used in combination.

In the epoxy resin composition according to the present invention, the microemulsion silica has a particle size of 5 to 200 nm. Here, if the particle size of the microemulsion silica is below 5 nm, the formation of roughness is insufficient. If the particle size thereof is above 200 nm, the formation of roughness is too large, and thus, fine line widths are difficult to form.

In the method for preparing microemulsion silica, the size of silicon nanoparticles is controllable to 5 to 200 nm by the method previously known in the art. For example, the surfactant is dissolved in oil having a long alkyl chain, and ammonia water is added thereto, to prepare an emulsion phase material. As the surfactant, a non-ionic or anionic surfactant may be generally used, and for example, aerosol OT (AOT), Brj30, NP4 or the like may be used. Here, if the concentration of the surfactant is increased, the size of generated silica particles is decreased but the number thereof is increased. Meanwhile, there may be 98% purity of n-heptane, n-decane, iso-octane, cyclohexane, toluene, and the like, in the oil having a long alkyl chain. Then, tetraethylorthosilicate (TEOS), which is a precursor of silica, is added onto the prepared emulsion phase material, thereby preparing silica nanoparticles.

Lastly, the prepared silica nanoparticles were centrifuged, followed by drying at about 60° C., so as to be made in a powder type. When the microemulsion silica is prepared by the above-described method, the silica particle is surrounded by surfactant, thereby providing a core shell structure.

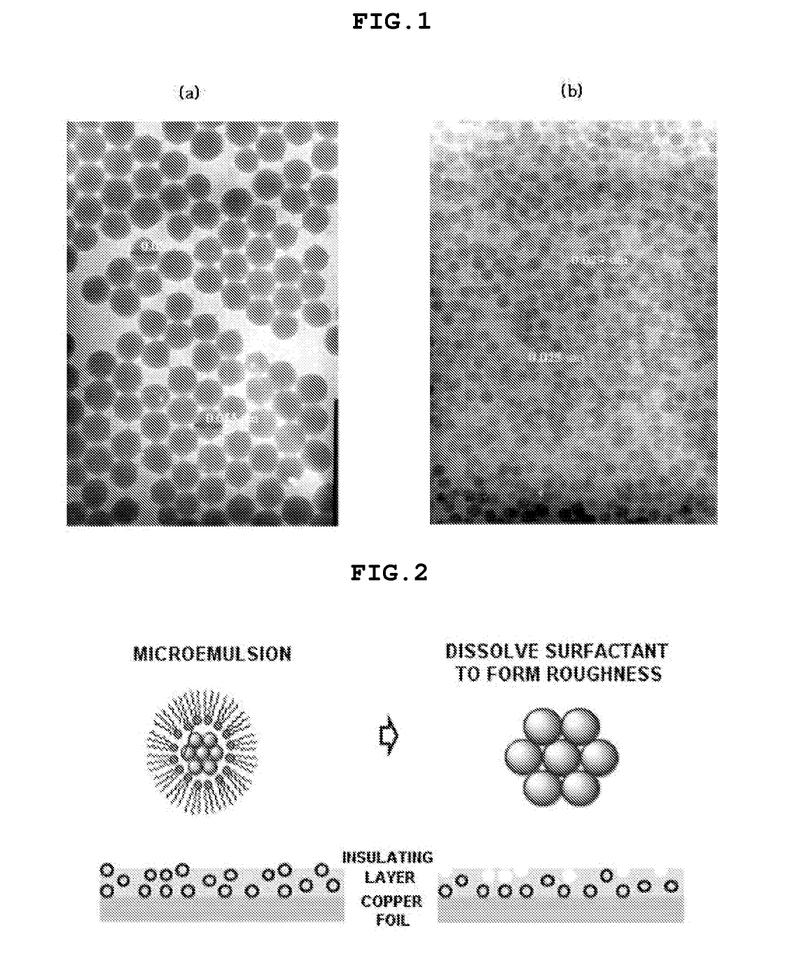

FIG. 1 shows TEM pictures of microemulsion silica particles contained in an epoxy resin composition according to one preferred embodiment of the present invention. In FIG. 1, (a) and (b) show transmission electron microscope (TEM) pictures of microemulsion silica particles, which are prepared by using 8% (a) and 15% (b) of the surfactant, respectively. In a case of using surfactant having a concentration of 8%, the size of silica particle is 50 to 55 nm. In a case of using surfactant having a concentration of 15%, the size of silica particle is 25 to 29 nm. Accordingly, it can be seen that an increase in the concentration of surfactant reduces the size of silica particle. As such, the size of silica particle can be controlled by varying the concentration of surfactant.

Meanwhile, the epoxy resin contained in the epoxy resin composition according to the present invention is an organic compound having at least one epoxy group. Here, the number of epoxy groups per one molecule of epoxy resin is 1, and preferably 2 or more.

As the epoxy resin, various kinds of epoxy resin known in the prior art may be used. Here, only one kind of epoxy resin may be used, or two or kinds of epoxy resin may be used in combination. Also, a derivative of the epoxy resin or a hydrogen additive of the epoxy resin may be included in the epoxy resin.

Examples of the epoxy resin may include an aromatic epoxy resin, an alicyclic epoxy resin, a Novolac epoxy resin, an aliphatic epoxy resin, a glycidyl ester epoxy resin, a glycidyl amine type epoxy resin, a glycidyl acryl type epoxy resin, a bisphenol A epoxy resin, a bisphenol F epoxy resin, a polyester type epoxy resin, and the like.

As a curing agent included in the epoxy resin composition according to the present invention, any material that can cure the epoxy resin may be used without particular limitation, and for example, curing agents known in the prior art may be used. Examples of the curing agent may include dicyandiamide, amine-based compounds, derivatives of the amine-based compounds, hydrazide compounds, melamine compounds, acid anhydrides, phenol compounds (phenol curing agent), activated ester compounds, benzoxazine compounds, maleimide compounds, heat-curable cationic polymerization catalysts, light-curable cationic polymerization initiators, cyanate ester resin, or the like. Also, derivatives of the above curing agents may be used as the curing agent. Also, one kind of the curing agent may be used, or two or more kinds of the curing agents may be used in combination. Also, a curing catalyst such as acetylacetone iron or the like may be used together with the curing agent.

In one preferred embodiment of the present invention, 15 to 40 wt % of the epoxy resin and 15 to 40 wt % of the curing agent are blended at an equivalent ratio of 0.8 to 1.2, and then the resulting material was completely dissolved in an organic solvent, for example, propylene glycol monomethyl ether acetate (PGMEA), methylethyl ketone (MEK), 2-methoxy ethanol, acetone, toluene, or the like. Here, the used amount of curing agent needs to be determined considering a blending ratio at which the epoxy resin can be completely cured.

A coefficient of thermal expansion of the substrate can be further decreased by including an inorganic filler in the epoxy resin composition of the present invention. Examples of the inorganic filler may include, but are not particularly limited thereto, silica, alumina, barium sulfate, talc, clay, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, and the like. Among them, silica is preferable. Also, silica such as amorphous silica, pulverized silica, molten silica, crystalline silica, synthetic silica, hollow silica, or the like, may be preferable, and molten silica is more preferable. Also, the silica is preferable in a sphere shape. Also, one kind of silica or two or more kinds of silica in combination may be used.

An average particle size of the inorganic filler is not particularly limited, but the upper limit of the average particle size of the inorganic filler is preferably 5 μm or less, more preferably 1 μm or less, and more preferably 0.7 μm or less, in view of forming fine patterns on an insulating substrate. Meanwhile, in a case where varnish is used as the epoxy resin composition, the lower limit of the average particle size of the inorganic filler is preferably 0.05 μm or more in view of increasing viscosity of the varnish and preventing the deterioration of the handling property.

In one preferred embodiment of the present invention, the used amount of the inorganic filler is preferably 20 to 70 wt %, which is added depending on a targeting coefficient of thermal expansion (CTE) of resin. The results are 25 ppm in a case of using 60 wt % of solid and 16 ppm in a case of using 68 wt % of solid, after the epoxy resin composition is made into a sheet. In other words, the inorganic filler needs to be added correspondingly to the relationship with coefficients of thermal expansion (CTEs) of products, which are required at the time of forming a substrate interlayer insulator.

The method for preparing the epoxy resin composition according to the present invention is not particularly limited. As an example of the method for preparing the epoxy resin composition, as necessary, components blended with the epoxy resin, the curing agent, and the microemulsion silica are added into the solvent, and then the resulting material is dried to remove the solvent.

The epoxy resin composition according to the present invention, for example, is preferably used in a material for a substrate for forming a core layer or a buildup layer of a multilayer substrate, an adhesive sheet, a laminate substrate, copper foil with resin, copper clad laminate, a printed circuit board, and the like.

Meanwhile, according to one preferred embodiment of the present invention, a printed circuit board of the present invention has a fine roughness, by using a method of preparing an epoxy resin composition including 15 to 40 wt % of an epoxy resin, 15 to 40 wt % of a curing agent, 20 to 70 wt % of an inorganic filler, and 1 to 5 wt % of microemulsion silica, sheeting the epoxy resin composition to manufacture a substrate, completely post-curing the manufactured substrate, and then removing the surfactant to detach silica particles therefrom.

The fine roughness of the substrate enables fine wirings to be formed on a surface of the substrate. A center line average arithmetic roughness on the surface of the substrate is normally 0.5 μm or less, after the sheet type substrate manufactured by using the epoxy resin composition is surface-treated.

More specifically, in the present invention, first, the epoxy resin composition is reacted (pre-cured or semi-cured), and then post-cured, thereby obtaining a completely cured reactant. In order to properly react the epoxy resin composition, it is preferable to react the epoxy resin composition by heating, radiating light, or the like.

The temperature at which the epoxy resin composition is reacted is not particularly limited. A heating temperature is preferably in a range of 130 to 190° C. If the heating temperature is below 130° C., the epoxy resin composition is not sufficiently cured, and thus, the surface roughness of the surface-treated substrate is prone to increase. If the heating temperature is above 190° C., a curing reaction of the epoxy resin composition is prone to rapid progress, which causes a curing degree thereof to be partially nonuniform, resulting in roughened regions and densified regions. As a result, the surface roughness of the substrate becomes increased.

The heating time for which the epoxy resin composition is reacted is not particularly limited. The heating time is preferably about 30 minutes or higher. If the heating time is below 30 minutes, the epoxy resin composition is not sufficiently cured, and thus, the surface roughness of the surface-treated substrate is prone to increase. The heating time is preferably 1 hour or less in view of increasing productivity.

A solvent that can dissolve the surfactant is used, at the time of desmear treatment for forming fine roughness on the surface of the substrate. Alcohol is generally used. In order to remove the surfactant, alcohol having a short chain is used to inflate a capping molecule, and alcohol having a long chain is used to facilitate detachment of the surfactant.

In forming roughness on an insulating substrate containing existing silica in the prior art, hydrofluoric acid or the like was used for detaching silica particles, but this had disadvantages in terms of environmental problems and permeation thereof into a bottom surface. However, in the surface treatment according to the present invention, surface roughness of the substrate can be effectively formed, without causing environmental problems by using alcohol.

Hereinafter, the present invention will be described in more detail with reference to the following Examples, but the scope of the present invention is not limited thereto.

### EXAMPLE 1

A. Preparation of Microemulsion Silica

13 wt % of aerosol OT (AOT), which is surfactant, was dissolved in 83 wt % of n-heptane, followed by addition of 4 wt % of ammonia water, thereby preparing an emulsion phase material. Then, tetraethylorthosilicate (TEOS), which is a precursor of silica, was added into the prepared emulsion phase material such that a mole ratio of ammonia water/TEOS reached 6, thereby preparing microemulsion silica nanoparticles having an average particle size of about 12.33 nm. Lastly, the prepared silica nanoparticles was centrifuged, followed by drying at about 60° C., thereby preparing a powder type of silica.

B. Preparation of Epoxy Resin Composition

Novolac epoxy (TDCN-500-80P) and rubber modified epoxy (KR-909) were mixed at a weight ratio of 1:1. 200 g of molten silica dispersion liquid having D90 of 200 nm or less, in which 60 wt % of solid is contained in 148 g of a resin solution prepared by mixing and stirring an amine-based heat curing agent (dicyandiamide) at an equivalent ratio of 1 eq., in 50 wt % of MEK, were added thereto. 60 g of a dispersion liquid having 10 wt % of the prepared microemulsion silica was added thereto. Then, the resultant mixture was stirred at a room temperature until it becomes a homogeneously solution, thereby obtaining an epoxy resin composition.

C. Manufacture of Substrate

A release-treated transparent polyethylene terephthalate (PET) film was prepared. A resin composition was coated on the PET film such that a thickness after drying using an applicator thereof reached about 50 μm Then, the resulting film was dried within a gear oven of about 100° C. for 12 minutes, thereby manufacturing a sheet type semi-cured substrate of 200 mm in length×200 mm in width×50 μm in thickness. The obtained sheet type semi-cured substrate was vacuum-laminated on a glass epoxy substrate, followed by reaction at about 150° C. for about 60 minutes. Then, the completely cured substrate was washed with alcohol for 2 minutes, thereby obtaining a substrate having fine roughness.

The procedure of forming surface roughness on the substrate including the microemulsion silica of the present invention manufactured as above was shown in FIG. 2. As shown in FIG. 2, a surface of the substrate including the microemulsion silica was desmear-treated, to dissolve out the surfactant contained in the microemulsion silica, resulting in the detachment of silica particles, thereby forming surface roughness on the substrate. The roughness of the substrate according to Example 1 was measured by forming roughness in a process A by using Newview 7200 from the Zygo Company, which is used as a 3D Optical Surface Profiler, estimating roughness values at 5 points, and averaging the roughness values. The resultant roughness was about 0.42 μm.

### EXAMPLE 2

A substrate was manufactured by the same procedure as Example 1 except that microemulsion silica having an average particle size of about 17.23 nm was prepared under the conditions of 15 wt % of NP 4, which is a surfactant, 1 wt % of ammonia water, and 84 wt % of iso-octane in step A of Example 1. The roughness of the substrate was measured by a 3D Optical Surface Profiler. The measured roughness was about 0.45 μm.

### EXAMPLE 3

A substrate was manufactured by the same procedure as Example 1 except that microemulsion silica having an average particle size of about 32 nm was prepared under the conditions of 15 wt % of Brj 30, which is a surfactant, 3 wt % of ammonia water, and 82 wt % of cyclohexane in step A of Example 1. The roughness of the substrate was measured by 3D Optical Surface Profiler. The measured roughness was about 0.46 μm.

As set forth above, the present invention can form roughness on the substrate in an ecofriendly and economic manner, by using the epoxy resin composition containing a core-shell structure of microemulsion silica surrounded by surfactant. Further, the present invention can realize high-reliability microcircuits by enhancing adhesive strength between a buildup substrate and a metal circuit layer.

Although the preferred embodiments of the present invention have been disclosed for illustrative purposes, they are for specifically explaining the present invention and thus an epoxy resin composition for forming a printed circuit board according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. An epoxy resin composition for forming a printed circuit board, comprising a core-shell structure of microemulsion silica surrounded by surfactant.

2. The epoxy resin composition as set forth in claim 1, wherein the epoxy resin composition is composed of 14 to 40 wt % of an epoxy resin, 15 to 40 wt % of a curing agent, 20 to 70 wt % of an inorganic filler, and 1 to 5 wt % of microemulsion silica.

3. The epoxy resin composition as set forth in claim 1, wherein the microemulsion silica has a particle size of 5 to 200 nm.

4. The epoxy resin composition as set forth in claim 2, wherein the epoxy resin is an aromatic epoxy resin, an alicyclic epoxy resin, a Novolac epoxy resin, an aliphatic epoxy resin, a glycidyl ester epoxy resin, a glycidyl amine type epoxy resin, a glycidyl acryl type epoxy resin, a bisphenol A epoxy resin, a bisphenol F epoxy resin, or a polyester type epoxy resin.

5. The epoxy resin composition as set forth in claim 2, wherein the curing agent is at least one selected from the group consisting of dicyandiamides, amine-based compounds, derivatives of amine-based compounds, hydrazide compounds, melamine compounds, acid anhydrides, phenol compounds (phenol curing agent), activated ester compounds, benzoxazine compounds, maleimide compounds, heat-curable cationic polymerization catalysts, light-curable cationic polymerization initiators, and cyanate ester resin.

6. The epoxy resin composition as set forth in claim 2, wherein the inorganic filler is molten silica.

7. A method for manufacturing a printed circuit board, comprising:
providing an epoxy resin composition including a core-shell structure of microemulsion silica surrounded by surfactant;
sheeting the epoxy resin composition to form a substrate; and
performing surface treatment on the formed substrate by completely post-curing the formed substrate and then removing the surfactant to detach silica particles therefrom.

8. The method as set forth in claim 7, wherein the epoxy resin composition is composed of 14 to 40 wt % of an epoxy resin, 15 to 40 wt % of a curing agent, 20 to 70 wt % of an inorganic filler, and 1 to 5 wt % of a microemulsion silica.

9. The method as set forth in claim 7, wherein the microemulsion silica has a particle size of 5 to 200 nm.

10. The method as set forth in claim 8, wherein the epoxy resin is an aromatic epoxy resin, an alicyclic epoxy resin, a Novolac epoxy resin, an aliphatic epoxy resin, a glycidyl ester epoxy resin, a glycidyl amine type epoxy resin, a glycidyl acryl type epoxy resin, a bisphenol A epoxy resin, a bisphenol F epoxy resin, or a polyester type epoxy resin.

11. The method as set forth in claim 8, wherein the curing agent is at least one selected from the group consisting of dicyandiamides, amine-based compounds, derivatives of amine-based compounds, hydrazide compounds, melamine compounds, acid anhydrides, phenol compounds (phenol curing agent), activated ester compounds, benzoxazine compounds, maleimide compounds, heat-curable cationic polymerization catalysts, light-curable cationic polymerization initiators, and cyanate ester resin.

12. The method as set forth in claim 8, wherein the inorganic filler is molten silica.

13. A printed circuit board manufactured in a sheet type by using the epoxy resin composition as set forth in claims 1, wherein the printed circuit board has a center line average arithmetic roughness of 0.5 μm or less, after the surface treatment is performed thereon.

14. A printed circuit board manufactured in a sheet type by using the epoxy resin composition as set forth in claims 2, wherein the printed circuit board has a center line average arithmetic roughness of 0.5 μm or less, after the surface treatment is performed thereon.

15. A printed circuit board manufactured in a sheet type by using the epoxy resin composition as set forth in claims 3, wherein the printed circuit board has a center line average arithmetic roughness of 0.5 μm or less, after the surface treatment is performed thereon.

16. A printed circuit board manufactured in a sheet type by using the epoxy resin composition as set forth in claims 4, wherein the printed circuit board has a center line average arithmetic roughness of 0.5 μm or less, after the surface treatment is performed thereon.

17. A printed circuit board manufactured in a sheet type by using the epoxy resin composition as set forth in claims 5, wherein the printed circuit board has a center line average arithmetic roughness of 0.5 μm or less, after the surface treatment is performed thereon.

18. A printed circuit board manufactured in a sheet type by using the epoxy resin composition as set forth in claims 6, wherein the printed circuit board has a center line average arithmetic roughness of 0.5 μm or less, after the surface treatment is performed thereon.
